(19) United States
(12) Patent Application Publication
(10) Pub. No.: US 2018/0069380 A1
(43) Pub. Date: Mar. 8, 2018

(54) Submersible Meter Box

(71) Applicant: John Giorgio, Cheshire, CT (US)

(72) Inventor: John Giorgio, Cheshire, CT (US)

(21) Appl. No.: 15/632,037

(22) Filed: Jun. 23, 2017

Related U.S. Application Data
(60) Provisional application No. 62/384,602, filed on Sep. 7, 2016.

(51) Int. Cl. H02B 1/06; G01R 11/04; H02B 1/03

(52) U.S. Cl. CPC H02B 1/06; G01F 15/14; H02B 1/03; G01R 11/04

(57) ABSTRACT

A submersible meter box is an apparatus that houses a meter submerged in water. The apparatus includes a housing and a meter adapter. The housing encloses the meter. The meter adapter mounts the meter and provides a continuous flow of current through the meter. The housing includes a receptacle, a cover, a meter opening, and a transparent protruding shield. The receptacle and the cover surround and enclose the meter adapter. The meter opening and the transparent protruding shield provide visibility of the meter within the housing. The meter adapter includes an input terminal and an output terminal. The input terminal and the output terminal provide electrical current to the meter via the engagement to cables and wires connected to buildings or devices. The cover is hermetically and detachably attached to the receptacle around an opening of the receptacle. The meter adapter is fixed within the receptacle, opposite to the cover.

The current application claims a priority to the U.S. Provisional Patent application Ser. No. 62/384,602 filed on Sep. 7, 2016.

### FIELD OF THE INVENTION

The present invention relates generally to meter boxes. More specifically, the present invention is a submersible meter box that protects a meter while submerged in water. The meter housed within the present invention is visible from the exterior of the submersible meter box.

### BACKGROUND OF THE INVENTION

Utility meters must be mounted higher in flood zone areas in order to prevent the electric current from being submerged in water. Meters exposed to water may result in corroded terminals or hazardous conditions such as a fire. In order to mount utility meters at a significant height in flood zone areas, ladders or construction lifts are needed. This is a cumbersome task and potentially, a dangerous task. Depending on the flood zone area, a meter is mounted at least fourteen feet from the ground.

The present invention provides a submersible meter box that eliminates the need to mount a meter at a significant height above the ground. The submersible meter box may house a variety of meters and prevents a contained meter from being damaged when submerged in water. The present invention serves as a means to fulfill the safety precaution in flood zone areas. A meter installed in flood zone areas and contained within the present invention is be able to be read and serviced whenever needed as a meter that is read and serviced in non-flood zone areas. The person reading and servicing the meter housed within the present invention does not need to use a ladder or a construction lift to reach the meter, thereby making the task easier, more convenient, and safer.

### BRIEF DESCRIPTION OF THE DRAWINGS

FIG. 1 is a perspective view of the present invention.

FIG. 2 is a left side view of the present invention.

FIG. 3 is a top side view of the present invention.

FIG. 4 is a top side view of the meter adapter fixed within the receptacle of the present invention.

FIG. 5 is an exploded view of the housing and the meter adapter fixed within the receptacle of the present invention.

### DETAILED DESCRIPTION OF THE INVENTION

All illustrations of the drawings are for the purpose of describing selected versions of the present invention and are not intended to limit the scope of the present invention.

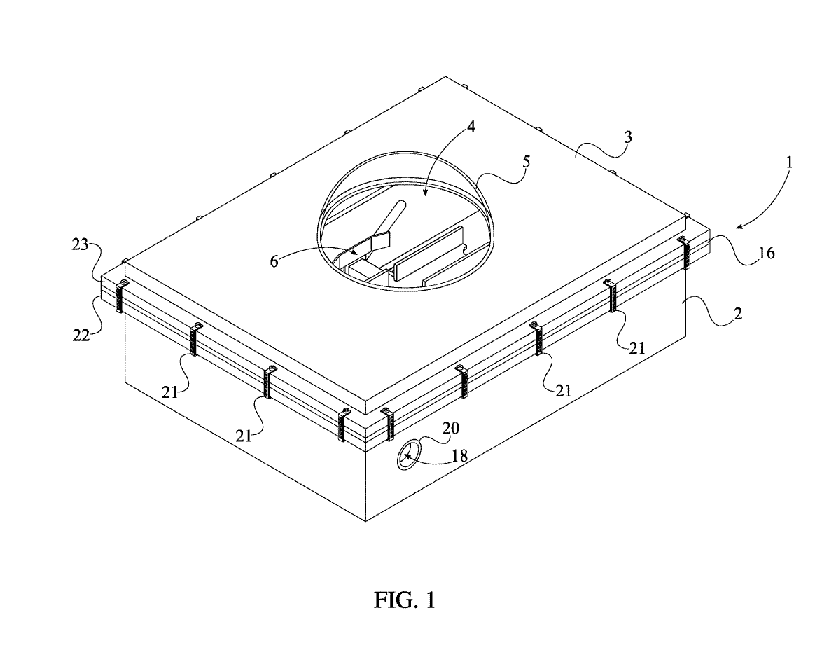

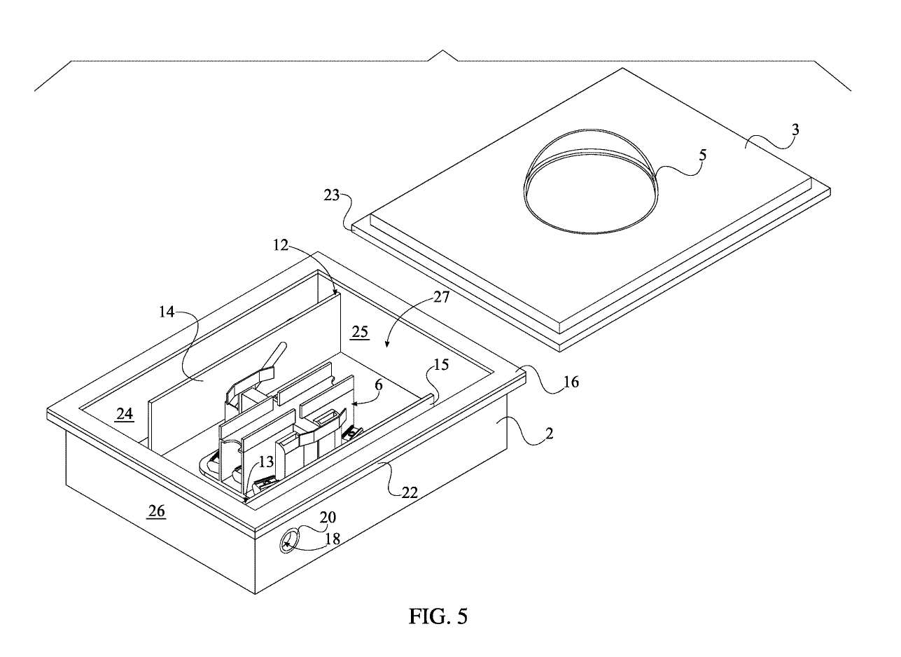

The present invention is a submersible meter box that houses a meter and prevents water from damaging the meter. The present invention is mounted at a desired height regardless if the meter is mounted within a flood zone area. As seen in FIG. 1 and FIG. 5, the present invention comprises a housing 1 and a meter adapter 6. The housing 1 encloses a meter and provides a dry, safe environment for the meter. The meter adapter 6 attaches a meter to the housing 1. More specifically, the meter adapter 6 mounts the meter within the housing 1 and provides the necessary electrical connections in order for a variety of cables and wires to be electrically couple to the meter. In order to effectively both contain the meter and make the meter accessible, the housing 1 comprises a receptacle 2, a cover 3, a meter opening 4, and a transparent protruding shield 5. The receptacle 2 upholds the meter adapter 6. The cover 3 seals the receptacle 2. The meter opening 4 allows meter to be visible from the exterior of the housing 1. The transparent protruding shield 5 encloses the meter opening 4, while preserving the visibility of the meter within the housing 1. In order for the meter to effectively measure electricity, the meter adapter 6 comprises an input terminal 7 and an output terminal 8. The input terminal 7 and the output terminal 8 provide a continuous current through the meter. Consequently, the meter measures the electricity usage of a building or device connected to the meter via a variety of cables and wires.

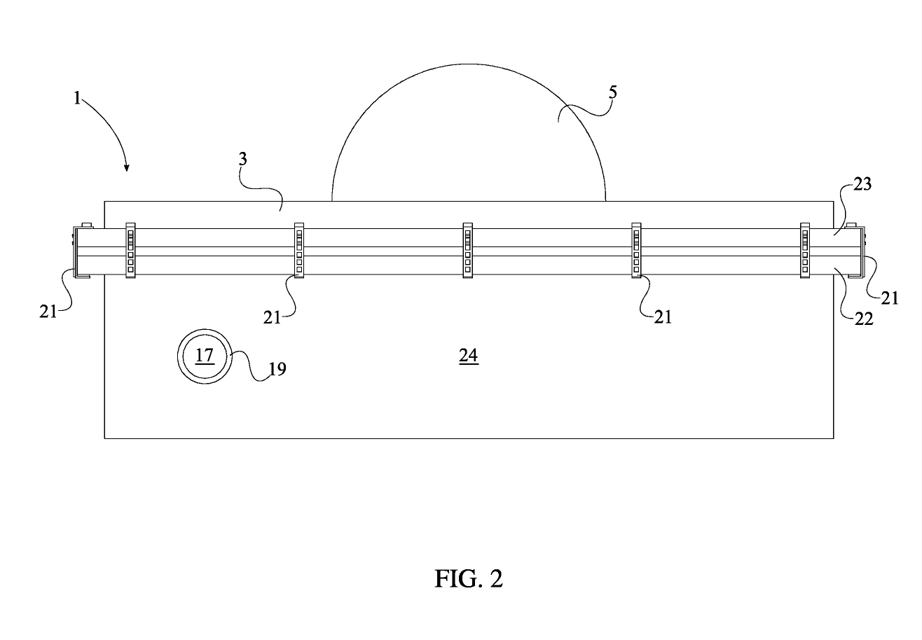

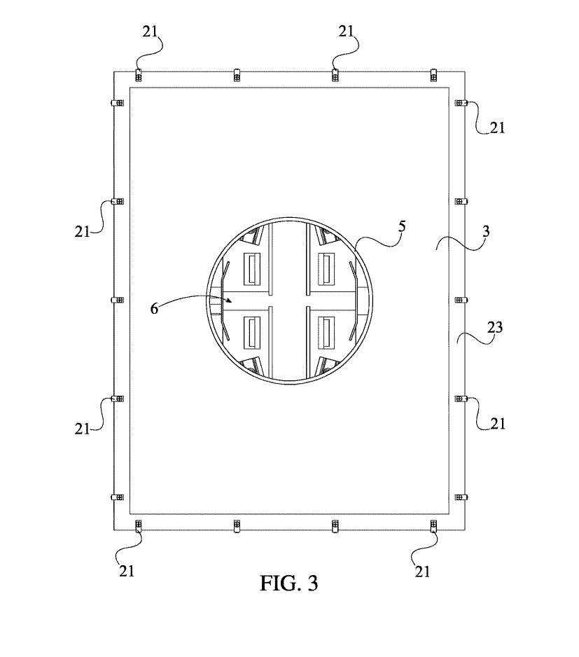

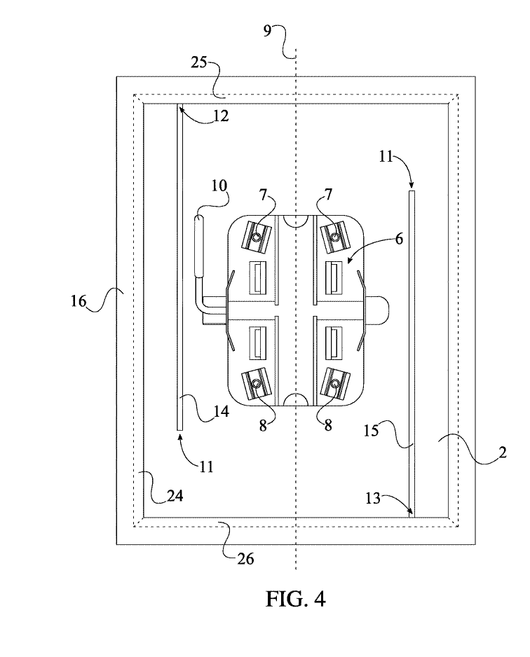

The overall configuration of the aforementioned components allows current to run through the meter while remaining safely contained. The cover 3 is hermetically and detachably attached to the receptacle 2 around an opening 27 of the receptacle 2. The hermetical arrangement of the cover 3 about the opening 27, as seen in FIG. 2 and FIG. 3, prevents water from entering the housing 1. The detachably attached engagement between the cover 3 and the receptacle 2 allows a user to access the meter within the housing 1. In order to view the meter within the housing 1 through the meter opening 4, the meter adapter 6 is fixed within the receptacle 2, opposite to the cover 3. The input terminal 7 and the output terminal 8 are oriented opposite to each other about the meter adapter 6. This configuration allows the present invention to accommodate a variety of meters. A central axis 9 of the meter adapter 6, illustrated in FIG. 4, is positioned coincident to the input terminal 7 and the output terminal 8. The meter opening 4 traverses through the cover 3 so a user may view the meter that is attached to the meter adapter 6. The transparent protruding shield 5 is positioned into the meter opening 4 and is perimetrically connected to the cover 3. This arrangement prevents water from entering the housing 1 through the meter opening 4.

The preferred embodiment of the present invention comprises an at least one accessory divider 11, illustrated in FIG. 4. The at least one accessory divider 11 organizes any cables and wires that traverse into the housing 1 and connect to the meter adapter 6. The at least one accessory divider 11 is mounted normal onto the receptacle 2 in order to keep any cables from obstructing the view of the meter mounted to the meter adapter 6. More specifically, the at least one accessory divider 11 is positioned in between the meter adapter 6 and an arbitrary lateral wall 24 of the receptacle 2, wherein the arbitrary lateral wall 24 is parallel to the central axis 9. This arrangement accommodates the preferred vertical orientation of the housing 1 about a mounting post or any comparable mountable surface. The at least one accessory divider 11 comprises a first divider end 12 and a second divider end 13, as seen in FIG. 4 and FIG. 5. The first divider end 12 is positioned coincident with a first adjacent lateral wall 25 of the receptacle 2, wherein the first adjacent lateral wall 25 is adjacent to the arbitrary lateral wall 24. The second divider end 13 is positioned offset with a second adjacent lateral wall 26 of the receptacle 2, wherein the second adjacent lateral wall 26 is adjacent to the arbitrary lateral wall 24. This arrangement accommodates the position of the input terminal 7 and the output terminal 8 of the meter adapter 6 and the cables and wires that correspond to input terminal 7 and the output terminal 8 respectively.

Furthermore, in the preferred embodiment of the present invention, the at least one accessory divider 11 comprises a first accessory divider 14 and a second accessory divider 15, as shown in FIG. 4 and FIG. 5. The first accessory divider 14 prevents any cables and wires attached to the input terminal 7 from obstructing the view of the meter within the housing 1. Similarly, the second accessory divider 15 prevents any cables and wires attached to the output terminal 8 from obstructing the view of the meter within the housing 1. The meter adapter 6 is positioned in between the first accessory divider 14 and the second accessory divider 15, ensuring the unhindered view of the meter. The first accessory divider 14 is preferably coincident to the first adjacent lateral wall 25 and the second accessory divider 15 is coincident the second adjacent lateral wall 26 in order to accommodate the position of the input terminal 7 and the output terminal 8 of the meter adapter 6 and the cables and wires that correspond to input terminal 7 and the output terminal 8, respectively. As the present invention may accommodate a variety of meters, in alternate embodiments of the present invention, the first accessory divider 14 and the second accessory divider 15 are coincident to either the first adjacent lateral wall 25 or the second adjacent lateral wall 26.

In order to ensure the waterproof environment within the housing 1, the present invention further comprises a gasket 16. The gasket 16 is positioned around the opening 27 of the receptacle 2 and is pressed in between the cover 3 and the receptacle 2, as illustrated in FIG. 4 and FIG. 5. This arrangement prevents water from entering the housing 1 while in a closed configuration.

In order for a variety of cables and wires to connect to the input terminal 7 and the output terminal 8 within the housing 1 and to a corresponding building or device, the preferred embodiment of the present invention further comprises an input hole 17 and an output hole 18. As seen in FIG. 2, the input hole 17 traverses through an arbitrary lateral wall 24 of the receptacle 2, wherein the arbitrary lateral wall 24 is parallel to the central axis 9. As seen in FIG. 1 and FIG. 5, the output hole 18 traverses through an opposing lateral wall of the receptacle 2, wherein the arbitrary lateral wall 24 is parallel to the central axis 9. This arrangement accommodates the arrangement of the input terminal 7 and the output terminal 8. More specifically, the input hole 17 and the output hole 18 are positioned perpendicular to the central axis 9 and are positioned offset from each other along the central axis 9. In order to prevent water from entering the housing 1 through the input hole 17 and the output hole 18, the preferred embodiment of the present invention comprises a first weatherproof lining 19 and a second weatherproof lining 20. The first weatherproof lining 19 is mounted into the input hole 17, and the second weatherproof lining 20 is mounted into the output hole 18. This arrangement secures cables and wires that traverses through the input hole 17 and the output hole 18 and preserves the dry, safe environment within the housing 1.

In order to secure the cover 3 to the receptacle 2, the present invention comprises a plurality of fasteners 21. The plurality of fasteners 21 is peripherally distributed onto the cover 3 so that the cover 3 is effectively secured to the receptacle 2, as shown in FIG. 1 and FIG. 3. Moreover, the cover 3 is detachably attached to the receptacle 2 by the plurality of fasteners 21. In the preferred embodiment of the present invention, the plurality of fasteners 21 is a set of C-clamps. However, it is understood that the plurality of fasteners 21 may be a variety of fasteners. The preferred embodiment of the present invention comprises a first flange 22 and a second flange 23. The first flange 22 and the second flange 23 allows the plurality of fasteners 21 to be easily attached and detached from the cover 3 and the receptacle 2. The first flange 22 is peripherally connected around the receptacle 2, adjacent to the opening 27 of the receptacle 2. Similarly, the second flange 23 is peripherally connected around the cover 3. This arrangement provides the structural support for the plurality of fasteners 21 to secure the cover 3 to the receptacle 2. More specifically, the first flange 22 is detachably attached to the second flange 23 by the plurality of fasteners 21.

In order to accommodate a variety of meters, the meter adapter 6 is a clamping meter socket. The meter adapter 6 further comprises a bypass lever 10, shown in FIG. 4 and FIG. 5. The bypass lever 10 not only mounts and dismounts a meter onto the meter adapter 6, but provides a continuous flow of electric current from the meter to the connected cables and wires. More specifically, the input terminal 7 and the output terminal 8 are electrically connected to each other through the bypass lever 10. A user may easily disconnect the meter from the meter adapter 6 and stop the flow of electric current in the event of an emergency.

Although the invention has been explained in relation to its preferred embodiment, it is to be understood that many other possible modifications and variations can be made without departing from the spirit and scope of the invention as hereinafter claimed.

What is claimed is:

1. A submersible meter box comprises:
a housing;
a meter adapter;
the housing comprises a receptacle, a cover, a meter opening, and a transparent protruding shield;
the meter adapter comprises an input terminal, an output terminal, and a central axis;
the cover being hermetically and detachably attached to the receptacle around an opening of the receptacle;
the meter adapter being fixed within the receptacle, opposite to the cover;
the input terminal and the output terminal being oriented opposite to each other about the meter adapter;
the central axis being positioned coincident to the input terminal and the output terminal;
the meter opening traversing through the cover;
the transparent protruding shield being positioned into the meter opening; and
the transparent protruding shield being perimetrically connected to the cover.

2. The submersible meter box as claimed in claim 1 comprises:
at least one accessory divider;
the at least one accessory divider being mounted normal onto the receptacle; and
the at least one accessory divider being positioned in between the meter adapter and an arbitrary lateral wall of the receptacle, wherein the arbitrary lateral wall is parallel to the central axis.

3. The submersible meter box as claimed in claim 2 comprises:
the at least one accessory divider comprises a first divider end and a second divider end;
the first divider end being positioned coincident with a first adjacent lateral wall of the receptacle, wherein the first adjacent lateral wall is adjacent to the arbitrary lateral wall; and
the second divider end being positioned offset with a second adjacent lateral wall of the receptacle, wherein the second adjacent lateral wall is adjacent to the arbitrary lateral wall.

4. The submersible meter box as claimed in claim 2 comprises:
the at least one accessory divider comprises a first accessory divider and a second accessory divider; and
the meter adapter being positioned into between the first accessory divider and the second accessory divider.

5. The submersible meter box as claimed in claim 1 comprises:
a gasket;
the gasket being positioned around the opening of the receptacle; and
the gasket being pressed in between the cover and the receptacle.

6. The submersible meter box as claimed in claim 1 comprises:
an input hole;
an output hole;
the input hole traversing through an arbitrary lateral wall of the receptacle, wherein the arbitrary lateral wall is parallel to the central axis;
the output hole through an opposing lateral wall of the receptacle, wherein the arbitrary lateral wall is parallel to the central axis;
the input hole and the output hole being positioned perpendicular to the central axis; and
the input hole and the output hole being positioned offset from each other along the central axis.

7. The submersible meter box as claimed in claim 6 comprises:
a first weatherproof lining; and
the first weatherproof lining being mounted into the input hole.

8. The submersible meter box as claimed in claim 6 comprises:
a second weatherproof lining; and
the second weatherproof lining being mounted into the output hole.

9. The submersible meter box as claimed in claim 1 comprises:
a plurality of fasteners;
the plurality of fasteners being peripherally distributed onto the cover; and
the cover being detachably attached to the receptacle by the plurality of fasteners.

10. The submersible meter box as claimed in claim 9 comprises:
a first flange;
a second flange;
the first flange being peripherally connected around the receptacle, adjacent to the opening of the receptacle;
the second flange being peripherally connected around the cover; and
the first flange being detachably attached to the second flange by the plurality of fasteners.

11. The submersible meter box as claimed in claim 1 comprises:
the meter adapter being a clamping meter socket;
the meter adapter comprises a bypass lever; and
the input terminal and the output terminal being electrically connected each other through the bypass lever.

12. A submersible meter box comprises:
a housing;
a meter adapter;
at least one accessory divider;
the housing comprises a receptacle, a cover, a meter opening, and a transparent protruding shield;
the meter adapter comprises an input terminal, an output terminal, and a central axis;
the meter adapter being a clamping meter socket;
the meter adapter comprises a bypass lever;
the cover being hermetically and detachably attached to the receptacle around an opening of the receptacle;
the meter adapter being fixed within the receptacle, opposite to the cover;
the input terminal and the output terminal being oriented opposite to each other about the meter adapter;
the central axis being positioned coincident to the input terminal and the output terminal;
the meter opening traversing through the cover;
the transparent protruding shield being positioned into the meter opening;
the transparent protruding shield being perimetrically connected to the cover;
the at least one accessory divider being mounted normal onto the receptacle;
the at least one accessory divider being positioned in between the meter adapter and an arbitrary lateral wall of the receptacle, wherein the arbitrary lateral wall is parallel to the central axis; and
the input terminal and the output terminal being electrically connected each other through the bypass lever.

13. The submersible meter box as claimed in claim 12 comprises:
the at least one accessory divider comprises a first divider end and a second divider end;
the first divider end being positioned coincident with a first adjacent lateral wall of the receptacle, wherein the first adjacent lateral wall is adjacent to the arbitrary lateral wall; and
the second divider end being positioned offset with a second adjacent lateral wall of the receptacle, wherein the second adjacent lateral wall is adjacent to the arbitrary lateral wall.

14. The submersible meter box as claimed in claim 12 comprises:
the at least one accessory divider comprises a first accessory divider and a second accessory divider; and
the meter adapter being positioned into between the first accessory divider and the second accessory divider.

15. The submersible meter box as claimed in claim 12 comprises:
a gasket;
the gasket being positioned around the opening of the receptacle; and
the gasket being pressed in between the cover and the receptacle.

16. The submersible meter box as claimed in claim 12 comprises:
an input hole;
an output hole;
the input hole traversing through an arbitrary lateral wall of the receptacle, wherein the arbitrary lateral wall is parallel to the central axis;
the output hole through an opposing lateral wall of the receptacle, wherein the arbitrary lateral wall is parallel to the central axis;
the input hole and the output hole being positioned perpendicular to the central axis; and
the input hole and the output hole being positioned offset from each other along the central axis.

17. The submersible meter box as claimed in claim 16 comprises:
a first weatherproof lining; and
the first weatherproof lining being mounted into the input hole.

18. The submersible meter box as claimed in claim 16 comprises:
a second weatherproof lining; and
the second weatherproof lining being mounted into the output hole.

19. The submersible meter box as claimed in claim 12 comprises:
a plurality of fasteners;
the plurality of fasteners being peripherally distributed onto the cover; and
the cover being detachably attached to the receptacle by the plurality of fasteners.

20. The submersible meter box as claimed in claim 19 comprises:
a first flange;
a second flange;
the first flange being peripherally connected around the receptacle, adjacent to the opening of the receptacle;
the second flange being peripherally connected around the cover; and
the first flange being detachably attached to the second flange by the plurality of fasteners.
